(19) United States
(12) Patent Application Publication
(10) Pub. No.: US 2026/0107485 A1
(43) Pub. Date: Apr. 16, 2026

(54) LATERAL SCHOTTKY DIODE

(71) Applicant: Infineon Technologies Dresden AG & CO. KG., Dresden (DE)

(72) Inventors: Clemens Mart, Dresden (DE); Swapnil Pandey, Dresden (DE); Jürgen Faul, Radebeul (DE); Henning Feick, München (DE)

(21) Appl. No.: 19/356,545

(22) Filed: Oct. 13, 2025

(30) Foreign Application Priority Data
Oct. 14, 2024 (DE) 102024129712.3

(51) Int. Cl. H10D 8/60; H10D 62/10; H10D 64/00

(52) U.S. Cl. CPC H10D 8/60; H10D 62/109; H10D 64/111

(57) ABSTRACT

A Schottky diode is disclosed. The Schottky diode includes: a drift region of a first doping type; a Schottky electrode connected to an anode node of the Schottky diode and adjoining the drift region; a Schottky contact formed between the Schottky electrode and the drift region; a shielding region of a second doping type complementary to the first doping type and connected to the Schottky electrode; a cathode region of the first doping type arranged in the drift region, spaced apart from the Schottky contact in a first lateral direction, and connected to a cathode node of the Schottky diode; and a compensation region of the second doping type adjoining the drift region and connected to the anode node. The shielding region at least partially laterally surrounds the Schottky contact.

### TECHNICAL FIELD

This disclosure relates in general to lateral Schottky diode.

### BACKGROUND

There is a need for a lateral Schottky diode with a high voltage blocking capability and a low leakage current.

### SUMMARY

One example relates to a Schottky diode. The Schottky diode includes a drift region of a first doping type, a Schottky electrode connected to an anode node of the Schottky diode and adjoining the drift region, a Schottky contact formed between the Schottky electrode and the drift region, a shielding region of a second doping type complementary to the first doping type and connected to the Schottky electrode, a cathode region of the first doping type arranged in the drift region spaced apart from the Schottky contact in a first lateral direction and connected to a cathode node of the Schottky diode, and a compensation region of the second doping type adjoining the drift region and connected to the anode node. The shielding region at least partially laterally surrounds the Schottky contact.

Examples are explained below with reference to the drawings. The drawings serve to illustrate certain principles, so that only aspects necessary for understanding these principles are illustrated. The drawings are not to scale. In the drawings the same reference characters denote like features.

### BRIEF DESCRIPTION OF THE DRAWINGS

FIG. 1 schematically illustrates a vertical cross-sectional view of one example of a lateral Schottky diode that includes a drift region, a compensation region, a Schottky electrode, a shielding region, a cathode region;

FIG. 2 illustrates a horizontal cross-sectional view of one example of a lateral Schottky diode of the type illustrated in FIG. 1;

FIG. 3 illustrates a horizontal cross-sectional view of another example of a lateral Schottky diode of the type illustrated in FIG. 1;

FIG. 4 illustrates a horizontal cross-sectional view of a lateral Schottky diode according to another example;

FIG. 5 illustrates a horizontal cross-sectional view of a lateral Schottky diode according to yet another example;

FIG. 6 illustrates one example for connecting the compensation region to an anode node in a Schottky diode of the type illustrated in FIG. 1;

FIGS. 7-9 illustrate vertical cross-sectional views of lateral Schottky diodes that further includes a first field electrode arrangement;

FIGS. 10A-10B illustrate vertical cross-sectional views of the lateral Schottky diode according to FIG. 5;

FIG. 11 illustrates a vertical cross-sectional view of a lateral Schottky diode that further includes a second field electrode arrangement;

FIGS. 12 and 13A-13B illustrate one example for connecting the Schottky electrode to an anode electrode and the cathode region to a cathode electrode of the Schottky electrode;

FIG. 14 illustrates one example for connecting a field electrode of the first field electrode arrangement to the anode electrode;

FIG. 15 illustrates one example for connecting a field electrode of the second field electrode arrangement to a cathode electrode;

FIG. 16 illustrates a modification of the lateral Schottky diode according to FIG. 1; and

FIG. 17 illustrates a vertical cross-sectional view of a lateral transistor device with a topology that is similar to the topology of the lateral Schottky diode according to FIG. 1.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

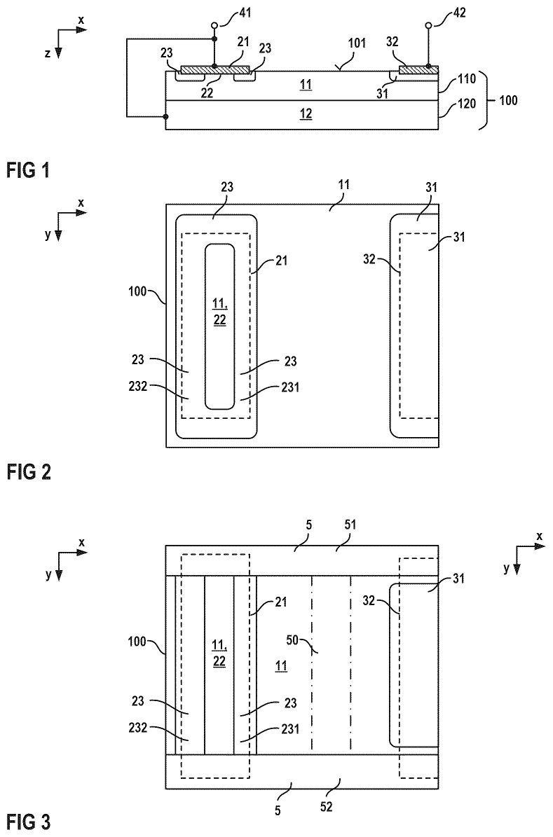

FIG. 1 illustrates a Schottky diode according to one example. The Schottky diode includes a drift region 11 of a first doping type, a Schottky electrode 21 adjoining the drift region 11, and a Schottky contact 22 formed between the Schottky electrode 21 and the drift region 11. Furthermore, the Schottky electrode includes a shielding region 23 of a second doping type complementary to the first doping type and connected to the Schottky electrode 21, a cathode region 31 of the first doping type arranged in the drift region 11 and spaced apart from the Schottky contact 22 in a first lateral direction x, and a compensation region 12 of the second doping type adjoining the drift region 11. The shielding region 23 at least partially laterally surrounds the Schottky contact 22.

Referring to FIG. 1, the Schottky electrode 21 and the compensation region 12 are connected to an anode node 41 and the cathode region 31 is connected to a cathode node 42 of the Schottky diode.

As the drift region 11 and the compensation region 12 are doped regions of complementary doping types a PN junction is formed between the drift region 11 and the compensation region 12. According to one example, the first doping type, which is the doping type of the drift region 11, is an N-type and the second doping type, which is the doping type of the compensation region 12, is a P-type.

According to one example, the compensation region 12, in the first lateral direction x extends along the drift region 11. According to one example, the compensation region 12, in the first lateral direction x, extends along the drift region 11 at least from a lateral position where the Schottky contact 22 is formed to a lateral position where the cathode region 31 is located. The compensation region 12 is spaced apart from both the Schottky contact 22 and the cathode region 31.

The drift region 11, the compensation region 12, the shielding region 23, and the cathode region 32 are doped semiconductor region of the same monocrystalline semiconductor material. According to one example, the semiconductor material is silicon (Si). According to another example, the semiconductor material is silicon carbide (SiC).

The Schottky contact 22 is a metal-semiconductor junction with rectifying characteristics and is formed by suitably selecting the material of the Schottky electrode 21 in view of the material of the drift region 11. Referring to the above, the drift region 11 is comprised of Si or SiC, for example. In each of these examples, a suitable material for implementing the Schottky electrode 21 is a metal such as aluminum (Al), gold (Au), nickel (Ni), platinum (Pt), titanium (Ti), palladium (Pd), or molybdenum (Mo), or a silicide, such as cobalt silicide (CoSi), tungsten silicide (WSi), titanium silicide (TiSi), or nickel silicide (NiSi). According to one example, a doping concentration of the drift region 11 is in a range of between 1E16 cm⁻³ and 1E18 cm⁻³, in particular between 5E16 cm⁻³ and 5E17 cm⁻³.

According to one example, as illustrated in FIG. 1, the drift region 11 with the shielding region 23 and the cathode region 32 embedded therein is arranged in a first semiconductor layer 110 of a semiconductor body 100 and the compensation region 12 is arranged in a second semiconductor layer 120 of the semiconductor body 100.

According to one example, the first semiconductor layer 110 is formed above the second semiconductor layer 120 in a vertical direction z of the semiconductor body 100, so that the first semiconductor layer 110 is arranged between the second semiconductor layer 120 and a first surface 101 of the semiconductor body 100. According to one example, the first surface 101 is formed by the first semiconductor layer 110. The vertical direction z is essentially perpendicular to the first lateral direction x in which the Schottky electrode 21 and the cathode region 31 are spaced apart from each other. FIG. 1 shows a vertical cross-sectional view of the Schottky diode in a section plane A-A defined by the vertical direction z and the first lateral direction x.

In the example illustrated in FIG. 1, the anode node 41 and the cathode node 42 of the Schottky diode are only schematically illustrated. Furthermore, electrical connections between the anode node 41 and the Schottky electrode 21 and the compensation region 12 and the electrical connection between the cathode region 31 and the cathode node 42 are only schematically illustrated. Examples for implementing the anode and cathode nodes 41, 42 nodes and the electrical connections are explained herein further below.

According to one example, the Schottky diode includes a cathode electrode 32 that adjoins the cathode region 31 and is connected to the cathode node 42. According to one example, a doping concentration of the cathode region 31 and the material of the cathode electrode 32 are adapted to one another such that a non-rectifying (ohmic) contact is formed between the cathode region 31 and the cathode electrode 32.

According to one example, the cathode electrode 32 includes a metal such as aluminum (Al), gold (Au), nickel (Ni), platinum (Pt), titanium (Ti), palladium (Pd), or molybdenum (Mo), or a silicide, such as cobalt silicide (CoSi), tungsten silicide (WSi), titanium silicide (TiSi), or nickel silicide (NiSi). The cathode electrode 32 can have the same material as the Schottky electrode 21 or a different material.

Doping concentrations of the doped device regions explained herein before are, for example,
Drift region 11: 5E16 cm⁻³-5E17 cm⁻³
Compensation region 12: 5E16 cm⁻³-5E17 cm⁻³
Shielding region 23: 5E19 cm⁻³-5E20 cm⁻³
Cathode region 31: 5E19 cm⁻³-5E20 cm⁻³.

According to one example, the Schottky electrode 21 and the optional cathode electrode 32 are formed above the first surface 101 of the semiconductor body 100. In the example illustrated in FIG. 1, the first surface 101 is formed by a surface of the first semiconductor layer 110. According to one example, the Schottky electrode 21 and the optional cathode electrode 32 partially extend into the semiconductor body 100, wherein at a junction between the electrodes 21, 32 and the semiconductor body 100 a metal-semiconductor-alloy may be formed.

According to one example, forming the Schottky electrode 21 includes forming a metal, such as cobalt (Co), tungsten (W), titanium (Ti), or nickel (Ni), above the drift region 11, and performing an annealing process in which a respective metal silicide is formed from the metal and the silicon (Si) or silicon carbide (SiC) of the semiconductor body 100 at an interface between the drift region 11 and the metal.

According to one example, the Schottky electrode 21 not only contacts the drift region 11 to form the Schottky contact 22, but also contacts the shielding region 23.

According to one example, a non-rectifying (ohmic) contact is formed between the Schottky electrode 21 and the shielding region 23.

Referring to the above, the compensation region 12 is connected to the anode node 41 and a PN junction is formed between the compensation region 12 and the drift region 11. Furthermore, a PN junction is formed between the shielding region 23, which may be connected to the Schottky electrode 21, and the drift region 11.

The Schottky diode can be operated in a conducting state or a blocking state. Whether the Schottky diode is in the conducting or the blocking state is dependent on the polarity of a voltage that can be applied between the anode node 41 and the cathode node 42.

The Schottky diode is in the conducting state when the polarity of the voltage between the anode and cathode nodes 41, 42 is such that the Schottky contact 22 formed between the Schottky electrode 21, that is connected to the anode node 41, and the drift region 11, that is connected to the cathode node 42, is forward biased. Referring to the above, the drift region 11 is an N-type region, for example. In this example, the Schottky diode is in the conducting state when a positive voltage is applied between the anode node 41 and the cathode node 42, that is, when the electrical potential at the anode node 41 is more positive than the electrical potential at the cathode node 41 and when a magnitude of the voltage is higher than a forward voltage of the Schottky contact 22. When the drift region 11 is an N-type region, the compensation region 12 and the shielding region 23 are P-type regions.

According to one example, the Schottky contact 22 is implemented such that its forward voltage is lower than the forward voltages of the PN junctions formed between the drift region 11 and the shielding and compensation regions 23, 12. In this case, the Schottky diode can be operated in the conducting state without the PN junctions between the drift region 11 and the shielding and compensation regions 23, 12 conducting at the same time.

In a Si based Schottky diode, for example, the forward voltage of the Schottky contact is in a range of between 0.2 V and 0.5 V and the forward voltage of the PN junctions is about 0.7V. In a SiC Schottky diode, for example, the forward voltage of the Schottky contact is between 1.0 V and 2.0 V, for example, and the forward voltage of the PN junctions is between 2.8 V and 3.6 V, for example. In SiC, the forward voltage of a PN junction, inter alia, is dependent on the polytype of the SiC material used.

The Schottky diode is in the blocking state when the polarity of the voltage applied between the anode node 41 and the cathode node 42 is such that the metal-semiconductor junction forming the Schottky contact 22 between the Schottky electrode 21 and the drift region 11 is reverse biased. The voltage that the reverse biases the Schottky contact 22 also reverse biases the PN junctions between the drift region 11 and the compensation and shielding regions 12, 23.

Reverse biasing the PN junction between the drift region 11 and shielding region 23 causes a depletion region to expand in the drift region 11 in a region adjacent to the Schottky contact 22. This depletion region protects the Schottky contact 22 from high electric fields that may occur when a magnitude of the voltage between the anode node 41 and the cathode node 42 increases and, therefore, helps to achieve a high breakdown voltage. The ‘breakdown voltage’ is the maximum reverse biasing voltage the Schottky diode can withstand without undergoing breakdown.

Reverse biasing the PN junction between the drift region 11 and the compensation region 12 causes a depletion region to expand in the drift region 11 in a region between the Schottky contact 22 and the cathode region 31. In this way, dopant charges included in the drift region 11 and resulting from first type dopant atoms included in the drift region 11 are at least partially compensated by dopant charges included in the compensation region 11 and resulting from second type dopant atoms included in the compensation region 12. This compensation effect makes it possible, at a given breakdown voltage of the Schottky diode, to implement the drift region 11 with a higher doping concentration than the drift region in a comparable Schottky diode that does not include a compensation region. Thus, the Schottky diode with the compensation region 12, in the conducting state, has a lower electrical resistance between the anode node 41 and the cathode node 42 than a comparable Schottky diode without compensation region 12.

Referring to the above, the shielding region 23 at least partially surrounds the Schottky contact 22 formed between the Schottky electrode 21 and the drift region 11. Different examples of shielding regions 23 that at least partially surround the Schottky contact 22 are illustrated in FIGS. 2-5, wherein each of FIGS. 2-5 shows a horizontal cross-sectional view of the Schottky diode in a section plane that is essentially parallel to the surface 101 and perpendicular to the vertical direction z.

In the example illustrated in FIG. 2, the shielding region 23 surrounds the Schottky contact 22 in lateral directions entirely. For this, the shielding region 23, in the lateral directions, forms a ring around the Schottky contact 22. A position of the Schottky electrode 21 above the Schottky electrode 22 and the shielding region 23 and a position of the cathode electrode 32 above the cathode region 31 is illustrated in dashed lines in FIG. 2.

According to another example illustrated in FIG. 3, the shielding region 23 includes two sections 231, 232 that are spaced apart from each other in the first lateral direction x. The Schottky contact 11 is arranged between the two shielding region sections 231, 232. According to one example, the Schottky diode further includes a trench isolation 5, such as an STI (shallow trench isolation). The trench isolation 5 includes an electrically insulating material, such as a semiconductor oxide or semiconductor nitride, arranged in a trench of the semiconductor body 100.

In the example illustrated in FIG. 3, the trench isolation 5 includes two sections 51, 52 that are spaced apart from each other in a second lateral direction y which is at least approximately perpendicular to the first lateral direction x. Each of the two shielding region sections 231, 232 extends between the two trench isolation sections 51, 52, so that a combination of the trench isolation 5 and the shielding region 23 surrounds the Schottky contact 22 in lateral directions entirely.

According to one example (not illustrated) the trench isolation 5, in lateral directions, forms a ring around the active regions of the Schottky diode. The ‘active regions’, include the drift region 11, the shielding region 23, and the cathode region 31.

According to one example illustrated in dashed-and-dotted lines in FIG. 3, a portion 50 of the trench isolation 5 is arranged in the drift region 11 between the Schottky contact 22 and the cathode region 32. In this example, the trench isolation 5, in the vertical direction of the drift region 11, does not entirely extend through the drift region 11, so that a portion of the drift region 11 remains below the trench isolation 5 that provides for an electrical connection between the Schottky contact 22 and the cathode region 32. A more detailed example of a portion 50 of the trench isolation 5 arranged in the drift region 11 is illustrated in FIG. 7 and explained herein further below.

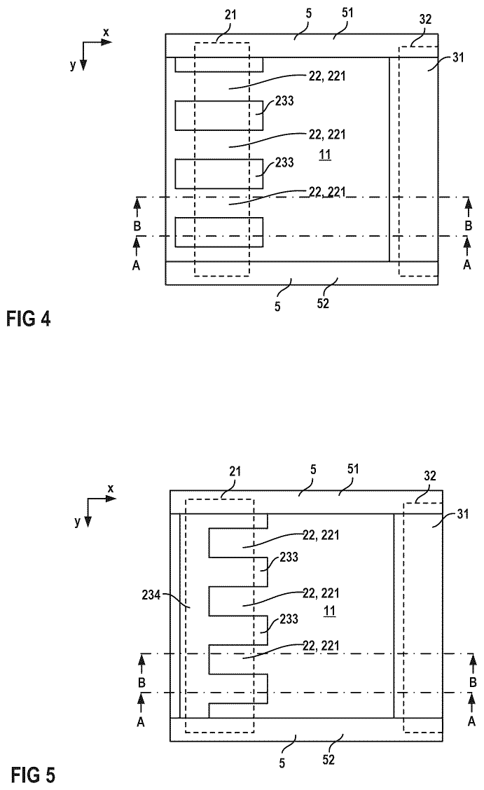

According to another example illustrated in FIG. 4, the shielding region 23 includes several sections 233 that are spaced apart from each other in the second lateral direction y. In this example, the Schottky contact 22 includes several sections 221, wherein each of these Schottky contact sections 221 is arranged between two neighboring shielding region sections 233. Each of the shielding region sections 233 is connected to the Schottky electrode 21. The position of the Schottky electrode 21 above the shielding region portions 233 and the drift region 11 is illustrated in dashed lines in FIG. 4. The shielding region sections 233 illustrated in FIG. 4 are also referred to as first shielding region sections in the following.

FIG. 5 shows a modification of the Schottky diode according to FIG. 4. In this example, the shielding region 23 further includes a second shielding region section 234 that adjoins the first shielding region sections 233 and extends in the second lateral direction y, so that the first shielding region sections 233 and the second shielding region section 234 form a comb-like structure, wherein the first shielding region sections 233 form fingers of the comb-like structure.

In both the example illustrated in FIG. 4 and the example illustrated in FIG. 5, the Schottky diode may include a trench isolation 5 of the type explained with reference to FIG. 3. In the example illustrated in FIG. 5, the second shielding region section 234 may extend between the two trench isolation sections 51, 52 and adjoin the two trench isolation sections 51, 52.

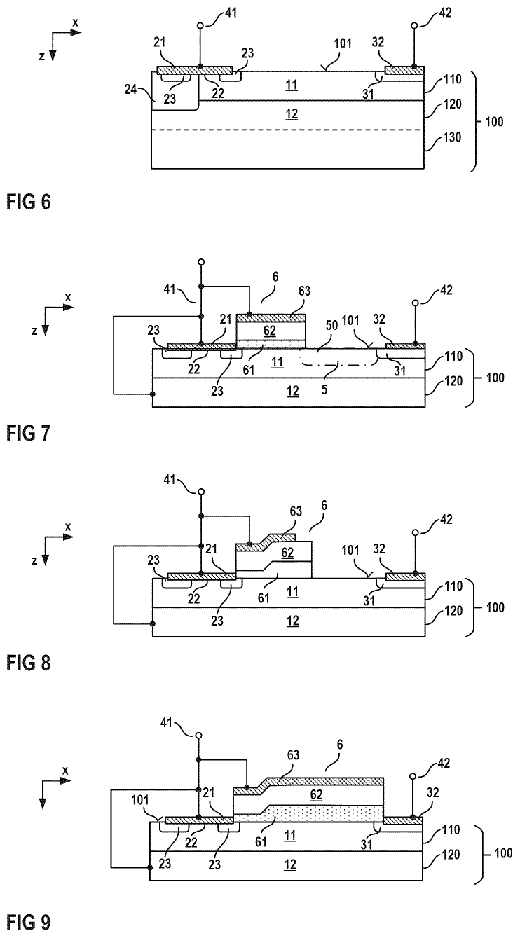

Referring to the above, the compensation region 12 is electrically connected to the anode node 41. One example for connecting the compensation region 12 to the anode node 41 is illustrated in FIG. 6. In this example, the Schottky diode includes a connection region 24 of the second doping type that extends from the compensation region 12 through the drift region 11 to the Schottky electrode 21 that is connected to the anode node 41. Portions of the shielding region 23 may be embedded in the connection region 24. The connection region may have a lower doping concentration than the shielding region 23. According to one example, the doping concentration of the connection region is between 5E17 cm⁻³ and 5E19 cm⁻³. The doping concentration of the shielding region 23 is between 10 times and 100 times the doping concentration of the connection region 24, for example.

In the example illustrated in FIG. 6 and in each of the examples explained herein before and herein below, the second semiconductor layer 120 may be arranged on top of a carrier 130. The carrier 130 is a semiconductor layer of one of the first and second doping types, for example.

For shaping the electric field in the drift region 11 when the Schottky diode is in the blocking state, the Schottky diode may include a field electrode arrangement 6 with a field electrode 62 connected to the anode node 41 and dielectrically insulated from the drift region 11. The shaping of the electric field in the drift region 11 may help to increase the breakdown voltage of the Schottky diode. Different examples of the field electrode arrangement 6 are illustrated in FIGS. 7-9 and explained in the following. Each of FIGS. 7-9 shows a vertical cross-sectional view of the Schottky diode according to one example.

Referring to FIGS. 7-9, the field electrode arrangement 6 includes the field electrode 62 that is arranged adjacent to the drift region 11, and a dielectric layer 61 that dielectrically insulates the field electrode 62 from the drift region 11. The dielectric layer 61 is also referred to as field electrode dielectric in the following. In the examples illustrated in FIGS. 7-9, the field electrode arrangement 6 is arranged above the first surface 101 of the semiconductor body 100.

The field electrode 62 is electrically conducting. The field electrode 62 may include a highly doped polycrystalline semiconductor material, such as polysilicon, or a metal, such as titanium (Ti), aluminum (Al), nickel (Ni), tungsten (W), or molybdenum (Mo). Furthermore, the field electrode arrangement 6 may include a contact electrode 63 that contacts the field electrode 62 and is electrically connected to the anode node 41. According to one example, the field electrode 62 includes polysilicon and the contact electrode includes a silicide, such as CoSi, TiSi, WSi, or NiSi. According to another example, the field electrode 62 includes a metal and the contact electrode includes the same metal as the field electrode 62 or a metal different from the metal of the field electrode 62.

An electrical connection between the anode node 41 and the contact electrode 63 of the field electrode arrangement 6 is only schematically illustrated in FIGS. 7-9.

According to one example, as illustrated in FIGS. 7-9, the field electrode arrangement 6, in the first lateral direction x, overlaps the shielding region 23. This may help to increase the robustness of the Schottky diode in the blocking state. In particular, the field electrode 62, similar to the compensation region 12, provides for a compensation of open charges included in the drift region 11, which helps to increase the voltage blocking capability and the reliability of the Schottky diode. The Schottky electrode 22 may adjoin the field electrode arrangement 6 (as illustrated) or may be arranged spaced apart from the field electrode arrangement 6 in the first lateral direction x (not illustrated).

According to one example illustrated in FIG. 7, the field electrode dielectric 61 at each position essentially has the same thickness. The ‘thickness’ of the field electrode dielectric 61 is the dimension of the field electrode dielectric 61 in the vertical direction z.

Referring to the above, the Schottky diode may include a trench isolation 5, wherein a portion 50 of the trench isolation 5 may be arranged in the drift region 11. FIG. 7 illustrates one example of the portion 50 of the trench isolation 5 arranged in the drift region 11 between the Schottky contact 22 and the cathode region 31. As illustrated, the trench isolation 5 extends from the first surface 101 into the drift region 11 and, in the vertical direction z, is spaced apart from the compensation region 12. In this way the trench isolation 5 is arranged between the Schottky context 22 and the cathode region 31 (and inevitably reduces a cross-sectional area of the drift region 11), but does not entirely interrupt the drift region 11. According to one example, in the vertical direction, the trench isolation 5 extends into the drift region 11 at least as deep as the cathode region 31.

Just as an example, a portion 50 of the trench isolation 5 arranged in the drift region 11 is only illustrated in FIG. 7. This, however, is only an example. A portion 50 of the trench isolation 5 arranged in the drift region 11 may be included in each of the examples explained herein before and in the following, although it is not illustrated.

According to another example illustrated in FIG. 8, the thickness of the field electrode dielectric 61 increases towards the cathode region 31. This includes that the field electrode dielectric 61 has at least two sections with different thicknesses such that the shorter the distance to the cathode region 31 the higher the thickness. In the example illustrated in FIG. 8, the field electrode dielectric 61 has two sections with different thicknesses and a transition section in which the thickness increases from a first thickness of a first one of the two sections to a second thickness of a second one of the two sections.

In the examples illustrated in FIGS. 7 and 8, the field electrode arrangement 6, in the first lateral direction x, is spaced apart from the cathode region 31. According to another example illustrated in FIG. 9, the field electrode arrangement 6, in the first lateral direction x, extends to the cathode region 31 or even overlaps the cathode region 31. The cathode electrode 32 may adjoin the field electrode arrangement 6 (as illustrated) or may be arranged spaced apart from the field electrode arrangement 6 (not illustrated).

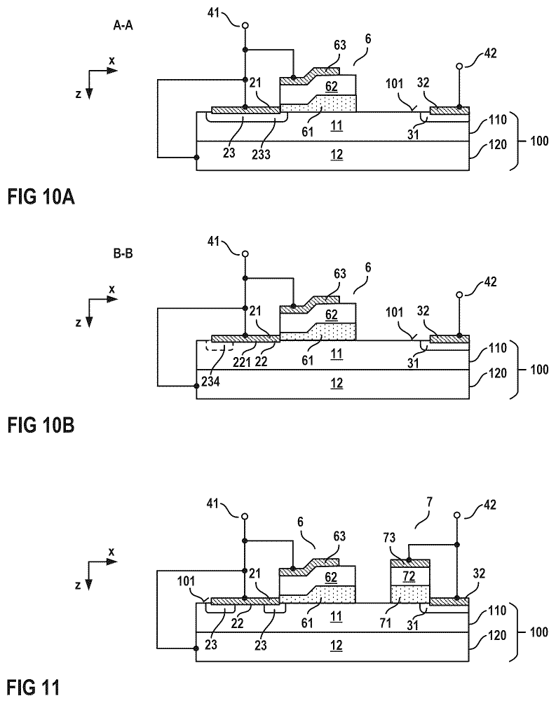

FIGS. 10A-10B show vertical cross-sectional views of a Schottky diode that includes a field electrode arrangement 6 and a shielding region 23 of the type illustrated in FIG. 4 or 5. FIG. 10A shows a vertical cross-sectional view in a first section plane A-A that cuts through one of the first shielding region sections 233, and FIG. 10B shows a vertical cross-sectional view in a second section plane B-B that is parallel to the first section plane A-A and cuts through one of the Schottky contact sections 221. The second shielding region section 234 illustrated in FIG. 10B is optional and is only present when the shielding region 23 is implemented in accordance with FIG. 5.

The field electrode arrangement 6 illustrated in FIGS. 10A-10B is in accordance with the field electrode arrangement 6 illustrated in FIG. 8. This, however, is only for illustration purposes. The field electrode arrangement 6 may be implemented in accordance with any of the examples illustrated in FIGS. 7 and 9 as well.

Referring to the above, the field electrode arrangement 6 may overlap the shielding region 23. In the example illustrated in FIGS. 10A and 10B, this includes that the field electrode arrangement 6, in the first lateral direction x, overlaps the first shielding region sections 233.

FIG. 11 illustrates a Schottky diode according to another example. In this example, the field electrode arrangement 6, in the lateral direction, is spaced apart from the cathode region 31. The field electrode arrangement illustrated in FIG. 6 is in accordance with the example illustrated in FIG. 8. This, however, is only for illustration purposes. The field electrode arrangement 6, which is also referred to as first field electrode arrangement in the following, may also be implemented in accordance with the example illustrated in FIG. 7.

In addition to the first field electrode arrangement 6, the Schottky diode illustrated in FIG. 6 further includes a second field electrode arrangement 7. The second field electrode arrangement 7 includes a field electrode 72 connected to the cathode region 42 and arranged adjacent to the drift region 11. The field electrode 72 is dielectrically insulated from the drift region 11 by a dielectric layer 71, which is also referred to as field electrode dielectric of the second field electrode arrangement 7 in the following. The field electrode 72 includes an electrically conducting material.

According to one example, the second field electrode arrangement 7 further includes a contact electrode 73 that contacts the field electrode 72 and is connected to the cathode node 42. An electrical connection between the contact electrode 73 and the cathode node 42 is only schematically illustrated in FIG. 11.

Referring to FIG. 11, the second field electrode arrangement 7, in the first lateral direction x, may overlap the cathode region 31. Furthermore, the cathode electrode 32 may adjoin the second field electrode arrangement 7 (as illustrated) or may be spaced apart from the second field electrode arrangement 7 (not illustrated). Furthermore, the field electrodes 62, 72 of the first and second field electrode arrangements 6, 7 and the corresponding contact electrodes 63, 73 are spaced apart from each other in the first lateral direction x. According to one example, (as illustrated) the dielectric layers 61, 71 are spaced apart from each other. According to another example (not illustrated) one contiguous dielectric layer forms the field electrode dielectrics 61, 71 of the first and second field electrode arrangements 6, 7.

In the example illustrated in FIG. 11, the shielding region 23 is in accordance with one of the examples illustrated in FIGS. 2 and 3. This, however, is only an example. The shielding region 23 is not restricted to implemented in this way but may be implemented in accordance with any of the examples explained herein before.

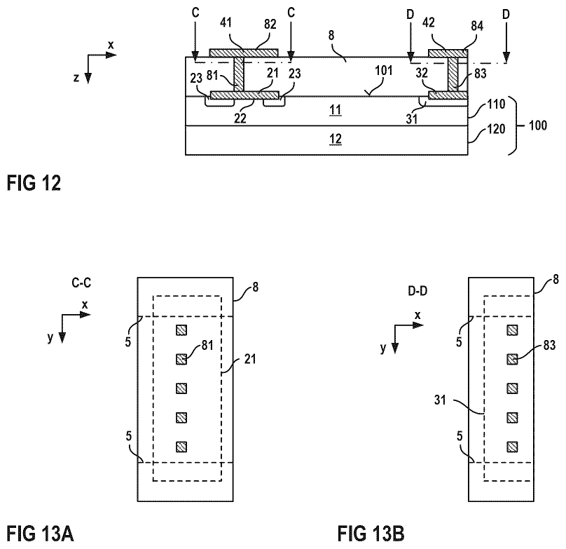

In the examples explained herein before, the anode and cathode nodes 41, 42 and electrical connections between the Schottky electrode 21 and the anode node 41 and between the cathode electrode 32 and the cathode node 42 are only schematically illustrated. One example for implementing the anode node 41, the cathode node 42 and the electrical connections is illustrated in FIG. 12, which shows a vertical cross-sectional view of a Schottky diode according to one example. In FIG. 12, the focus is on illustrating the implementation of the anode and cathode nodes 41, 42 and the electrical connections. Thus, field electrode arrangements, such as field electrode arrangements 6, 7 explained herein before, are not illustrated in FIG. 12. Nevertheless, a Schottky diode of the type illustrated in FIG. 12 may include at least one of such field electrode arrangements. Furthermore, in the example illustrated in FIG. 12, the shielding region 23 is in accordance with one of the examples illustrated in FIGS. 2 and 3. This, however, is only for illustration purposes. Any type of shielding region 23 explained herein before may be used in the Schottky diode of the type illustrated in FIG. 12.

Referring to FIG. 12, the Schottky diode includes a passivation layer 8 formed on top of the first surface 101 of the semiconductor body 100. The passivation layer 8 includes at least one layer of an electrically insulating material. According to one example, the passivation layer 8 is a homogeneous layer of only one material. According to another example, the passivation layer 8 includes two or more insulating layers of different materials. According to one example, the at least one layer is an oxide layer, a nitride layer, or the like.

According to one example, the anode node 41 is an electrically conducting layer 82 formed on top of the passivation layer 8 and the cathode node 42 is an electrically conducting layer 84 formed on top of the passivation layer 8, which may also be referred to as ILD (inter-level dielectric). The electrically conducting layers 82, 84 include a metal, for example. According to one example, the metal is copper (Cu), aluminum (Al), silver (Ag), gold (Au), platinum (Pt), or tungsten (W).

Furthermore, the Schottky electrode 21 is connected to the conducting layer 82 forming the anode node 41 through at least one electrically conducting first via 81 that, in the vertical direction z, extends from the electrically conducting layer 82 through the passivation layer 8 to the Schottky electrode 21. The cathode electrode 32 is connected to the conducting layer 84 forming the cathode node 41 through at least one electrically conducting second via 83 that, in the vertical direction z, extends from the electrically conducting layer 84 through the passivation layer 8 to the cathode electrode 32.

According to one example illustrated in FIG. 13A, which shows a horizontal cross-sectional view of the passivation layer 8 in a section between the Schottky electrode 21 and the electrode layer 82 forming the anode node 41, the Schottky diode may include several first vias 81 that are spaced apart from each other in the second lateral direction y. The outline of the Schottky electrode 21 arranged below the passivation layer 8 is illustrated in dashed lines in FIG. 13B.

According to one example, the electrically conducting vias 81, 83 include a metal such as tungsten (W), copper (Cu), aluminum (Al), or titanium (Ti).

According to one example illustrated in FIG. 13B, which shows a horizontal cross-sectional view of the passivation layer 8 in a section between the cathode electrode 32 and the electrode layer 84 forming the cathode node 42, the Schottky diode may include several second vias 83 that are spaced apart from each other in the second lateral direction y. The outline of the cathode electrode 32 arranged below the passivation layer 8 is illustrated in dashed lines in FIG. 13B.

It should be noted that the semiconductor body 100 with the active regions of the Schottky diode integrated therein may be arranged in a semiconductor package, such as a mold compound package. In this example, the anode node 41 and the cathode node 42 may be connected to contacts that are accessible at the outside of the semiconductor package through bond wires, clips, or the like. This is commonly known, so that no further explanation is required in this regard.

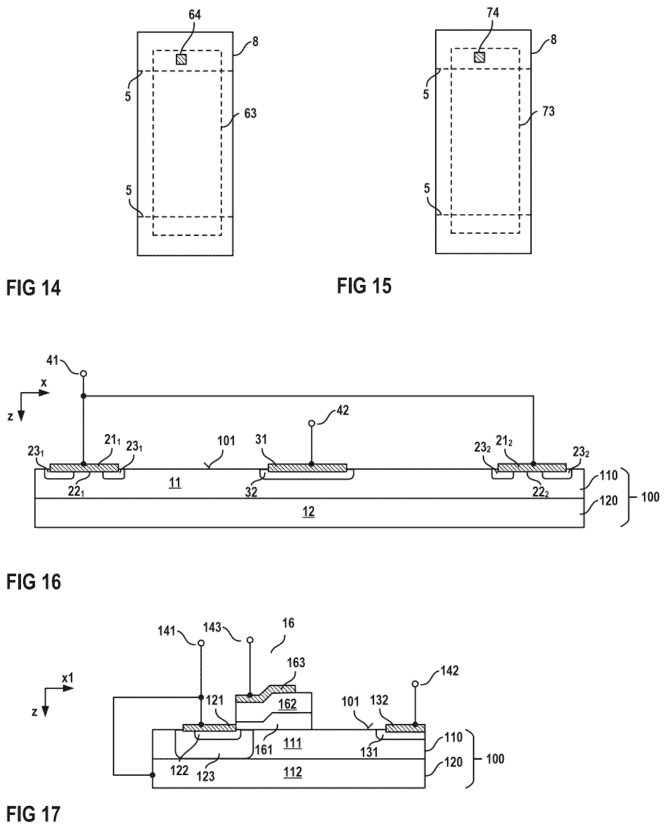

Referring to the above, the field electrode 63 of the first field electrode arrangement 6 is connected to the anode node 41 of the Schottky electrode. According to one example, the Schottky diode includes a trench isolation 5 of the type explained hereinabove, the field electrode 63, in the second lateral direction y, overlaps the trench isolation 5, and the first field electrode arrangement 6 is covered by (embedded in) the passivation layer 8. In this example, the Schottky diode may include an electrically conducting via 64 that is arranged above the trench isolation 5 and extends through the passivation layer 8 down to the field electrode 63. This is illustrated in FIG. 14, which shows a top view of the passivation layer 8 and the electrically conducting via 64 arranged above the trench isolation 5. The position of the trench isolation 5 below the passivation layer is illustrated in dashed lines in FIG. 14.

The electrically conducting via 84 is connected to the anode node 41. The anode node 41 may be implemented by an electrically conducting layer 82 of the type illustrated in FIG. 12. According to one example, this electrically conducting layer 82 covers the electrically conducting via 64, so that the electrically conducting via 64 is directly connected to the conducting layer 82 forming the anode node 41.

Referring to the above, the field electrode 73 of the second field electrode arrangement 7 is connected to the cathode node 42 of the Schottky electrode. According to one example, the Schottky diode includes a trench isolation 5 of the type explained hereinabove, the field electrode 73, in the second lateral direction y, overlaps the trench isolation 5, and the second field electrode arrangement 7 is covered by (embedded in) the passivation layer 8. In this example, the Schottky diode may include an electrically conducting via 74 that is arranged above the trench isolation 5 and extends through the passivation layer 8 down to the field electrode 73. This is illustrated in FIG. 15, which shows a top view of the passivation layer 8 and the electrically conducting via 74 arranged above the trench isolation 5. The position of the trench isolation 5 below the passivation layer is illustrated in dashed lines in FIG. 15.

The electrically conducting via 74 is connected to the cathode node 42. The cathode node 42 may be implemented by an electrically conducting layer 84 of the type illustrated in FIG. 12. According to one example, this electrically conducting layer 84 covers the electrically conducting via 84, so that the electrically conducting via 74 is directly connected to the conducting layer 84 forming the cathode node 41.

According to one example illustrated in FIG. 16, the Schottky diode includes two anode arrangements that each include a Schottky electrode 21₁, 21₂ forming a Schottky contact 22₁, 22₂ with the drift region 11 and a shielding region 23₁, 23₂ and that are each laterally spaced apart from the cathode region 32. Relative to the cathode region 32, the two anode arrangements are symmetrical. The Schottky contact 21₁, 21₂ of each of the two anode arrangements is connected to the anode node 41.

The focus of FIG. 16 is on illustrating a Schottky diode with two symmetrical anode arrangements. It should be noted that, although the anode arrangements are illustrated in accordance with one of the examples shown in FIGS. 2 and 3, the anode arrangements are not restricted to implemented in this way. Instead, any other type of anode arrangements explained herein before may be used as well. Furthermore, the Schottky diode may include at least one of the first and second field electrode arrangements explained herein before, although such field electrode arrangements are not illustrated in FIG. 16.

Referring to the above, active regions of the Schottky diode may be implemented in a semiconductor body 100. According to one example, further semiconductor devices, such as lateral transistor devices, are implemented in the same semiconductor body 100. In this example, aa trench isolation 5 of the type explained herein before may be arranged between a region of the semiconductor body 100 in which the Schottky diode is implemented and a region of the semiconductor body 100 in which a further semiconductor device is implemented. As used herein, the expression “a semiconductor device, such as the Schottky diode or the further semiconductor device, implemented in the semiconductor body 100” includes that doped regions of the semiconductor device are integrated in the semiconductor body 100 and further regions of the semiconductor device, such as electrodes, are formed in the semiconductor body 100 and/or above a surface, such as the first surface 101 of the semiconductor body 100.

One example of a lateral transistor device that may be implemented in the same semiconductor body 100 as the Schottky diode is illustrated in FIG. 17. The transistor device is implemented as a MOSFET and has a topology similar to the topology of the Schottky diode.

Referring to FIG. 17, the transistor device includes a drift region 111 of the first doping type and a compensation region 112 of the second doping type complementary to the first doping type. The drift region 111 may be formed in the first semiconductor layer 110 and may have the same doping concentration of the drift region 11 of the Schottky diode. The compensation region 112 may be formed in the second semiconductor layer 120 and may have the same doping concentration as the compensation region 12 of the Schottky diode.

Referring to FIG. 17, the transistor device further includes a body region 123 of the second doping type arranged in the drift region 112 and a source region 122 embedded in the body region 123. A source electrode 121 formed above the first surface 101 of the semiconductor body 100 is connected to both the source region 122 and the body region 123. The compensation region 112 and the source electrode 121 are connected to a source node 141 of the transistor device. Everything explained herein before regarding connecting the Schottky electrode 21 and the compensation region 12 of the Schottky diode to the anode node 41 applies to connecting the source electrode 121 and the compensation region 112 of the transistor device to the source node 141 accordingly.

Referring to FIG. 17, the transistor device further includes a drain region 131 of the first doping type that is spaced apart from the source and body regions 122, 123 in a lateral direction x1. This lateral direction x1 may correspond to the first lateral direction x of the Schottky diode or may be different from the first lateral direction x of the Schottky diode. A drain electrode 132 is connected to the drain region 131, and the drain electrode 132 is connected to a drain node 141 of the transistor device.

Furthermore, the transistor device includes a gate electrode 162 that is dielectrically insulated from the body region 123 by a gate dielectric 161 and is configured to control a conducting channel in the body region 123 between the source region 122 and the drift region 111. Through a contact electrode 163, the gate electrode 162 is connected to a gate node 143 of the transistor device, for example.

According to one example, the doping concentration of the body region 123 equals the doping concentration of the shielding region 23 of the Schottky diode and the doping concentration of the drain region 131 equals the doping concentration of the cathode region 31. Thus, the body region 123 and the shielding region 23 may be formed by the same process, and the drain region 131 and the cathode region 31 may be formed by the same process. Furthermore, a gate arrangement 16 with the gate electrode 162, the gate dielectric 161, and the gate electrode 163 may have the same form as the first field electrode arrangements 6, so that the first electrode arrangement 6 and the gate arrangement 16 may be formed by the same process steps.

Thus, the Schottky diode explained herein before node not only has a high breakdown voltage, but at least portions of the Schottky diode may be produced in an efficient way by the same process steps by which portions of a lateral transistor device implemented in the same semiconductor body 100 are formed.

Some of the aspects explained above are briefly summarized in the following with reference to numbered examples.

Example 1. A Schottky diode, including: a drift region of a first doping type; a Schottky electrode connected to an anode node of the Schottky diode and adjoining the drift region; a Schottky contact formed between the Schottky electrode and the drift region; a shielding region of a second doping type complementary to the first doping type and connected to the Schottky electrode; a cathode region of the first doping type arranged in the drift region spaced apart from the Schottky contact in a first lateral direction and connected to a cathode node of the Schottky diode; and a compensation region of the second doping type adjoining the drift region and connected to the anode node, wherein the shielding region at least partially laterally surrounds the Schottky contact.

Example 2. The Schottky diode of example 1, wherein the shielding region includes a first shielding region section and a second shielding region section that are spaced apart from each other in the first lateral direction, and wherein the Schottky contact is arranged between the first and second sections.

Example 3. The Schottky diode of example 1, wherein the shielding region includes a plurality of first shielding region sections that are spaced apart from each other in a second lateral direction different from the first lateral direction, and wherein the Schottky contact includes a plurality of Schottky contact sections each arranged between a respective pair of neighboring first shielding region sections.

Example 4. The Schottky diode of example 3, wherein the shielding region further includes a second shielding region section extending in a second lateral direction and adjoining the first shielding region sections.

Example 5. The Schottky diode of any one of the preceding examples, further including: a first field electrode arrangement including a first field electrode dielectrically insulated from the drift region by a first field electrode dielectric, wherein the first field electrode is electrically connected to the anode node.

Example 6. The Schottky diode of example 5, wherein the first field electrode arrangement, in the first lateral direction, overlaps the shielding region.

Example 7. The Schottky diode of example 5 or 6, wherein the first field electrode arrangement is spaced apart from the cathode region in the first lateral direction.

Example 8. The Schottky diode of example 7, further including: a second field electrode arrangement including a second field electrode dielectrically insulated from the drift region by a second field electrode dielectric, wherein the second field electrode is electrically connected to the cathode node.

Example 9. The Schottky diode of example 5 or 6, wherein the first field electrode arrangement, in the first lateral direction overlaps the cathode region.

Example 10. The Schottky diode of any one of the preceding examples, wherein the drift region, the shielding region, and the cathode region are arranged in a first semiconductor layer formed on top of a second semiconductor layer, and wherein the compensation region is arranged in the second semiconductor layer.

Example 11. The Schottky diode of example 10, further including: a third semiconductor layer, wherein the second semiconductor layer is formed on top of the third semiconductor layer.

Example 12. The Schottky diode of example 10, further including: a trench isolation arranged at least in the first semiconductor layer, wherein the trench isolation includes a first isolation section and a second isolation section that are spaced apart from each other in a second lateral direction of the drift region, and wherein the drift region is arranged between the first and second isolation sections.

Example 13. The Schottky diode of any one of the preceding examples, wherein the compensation region is spaced apart from the first electrode in a vertical direction of the drift region, and wherein the Schottky diode further includes a contact region of the second doping type connecting the compensation region to the first electrode.

Example 14. The Schottky diode of any one of the preceding examples, further including: an insulating layer formed on top of the Schottky electrode.

Example 15. The Schottky diode of example 14, further including: an anode electrode; at least one electrically conducting via extending in the insulating layer between the anode electrode and the Schottky electrode.

Example 16. The Schottky diode of example 14 or 15, further including: a cathode electrode; at least one electrically conducting via extending in the insulating layer between the cathode electrode and the Schottky electrode.

Example 17. A semiconductor arrangement, including: a Schottky diode according to any one of examples 1 to 16; and a lateral transistor device, wherein the Schottky diode and the lateral transistor device are implemented in the same semiconductor body.

Example 18. The semiconductor arrangement according to example 17, wherein the lateral transistor device includes: a drift region of the first doping type; a body region of the second doping type; and a drain region of the first doping type, and wherein the body region and the shielding region of the Schottky diode at least approximately have the same doping concentration.

Example 19. The semiconductor arrangement according to example 18, wherein the drift region of the lateral transistor device and the drift region of the Schottky diode at least approximately have the same doping concentration.

Example 20. The semiconductor arrangement according to example 18 or 19, wherein the drain region of the lateral transistor device and the cathode region of the Schottky diode at least approximately have the same doping concentration.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A Schottky diode, comprising:
a drift region of a first doping type;
a Schottky electrode connected to an anode node of the Schottky diode and adjoining the drift region;
a Schottky contact formed between the Schottky electrode and the drift region;
a shielding region of a second doping type complementary to the first doping type and connected to the Schottky electrode;
a cathode region of the first doping type arranged in the drift region, spaced apart from the Schottky contact in a first lateral direction, and connected to a cathode node of the Schottky diode; and
a compensation region of the second doping type adjoining the drift region and connected to the anode node,
wherein the shielding region at least partially laterally surrounds the Schottky contact.

2. The Schottky diode of claim 1,
wherein the shielding region comprises a first shielding region section and a second shielding region section that are spaced apart from each other in the first lateral direction, and
wherein the Schottky contact is arranged between the first and second sections.

3. The Schottky diode of claim 1,
wherein the shielding region comprises a plurality of first shielding region sections,
wherein the first shielding region sections are spaced apart from each other in a second lateral direction different from the first lateral direction, and
wherein the Schottky contact comprises a plurality of Schottky contact sections each arranged between a respective pair of neighboring ones of the first shielding region sections.

4. The Schottky diode of claim 3,
wherein the shielding region further comprises a second shielding region section extending in a second lateral direction and adjoining the first shielding region sections.

5. The Schottky diode of claim 1, further comprising:
a first field electrode arrangement including a first field electrode dielectrically insulated from the drift region by a first field electrode dielectric,
wherein the first field electrode is electrically connected to the anode node.

6. The Schottky diode of claim 5,
wherein the first field electrode arrangement, in the first lateral direction, overlaps the shielding region.

7. The Schottky diode of claim 5,
wherein the first field electrode arrangement is spaced apart from the cathode region in the first lateral direction.

8. The Schottky diode of claim 7, further comprising:
a second field electrode arrangement including a second field electrode dielectrically insulated from the drift region by a second field electrode dielectric, wherein the second field electrode is electrically connected to the cathode node.

9. The Schottky diode of claim 5,
wherein the first field electrode arrangement overlaps the cathode region in the first lateral direction.

10. The Schottky diode of claim 1,
wherein the drift region, the shielding region, and the cathode region are arranged in a first semiconductor layer formed on top of a second semiconductor layer, and
wherein the compensation region is arranged in the second semiconductor layer.

11. The Schottky diode of claim 10, further comprising:
a third semiconductor layer,
wherein the second semiconductor layer is formed on top of the third semiconductor layer.

12. The Schottky diode of claim 10, further comprising:
a trench isolation arranged at least in the first semiconductor layer,
wherein the trench isolation includes a first isolation section and a second isolation section that are spaced apart from each other in a second lateral direction of the drift region, and
wherein the drift region is arranged between the first and second isolation sections.

13. The Schottky diode of claim 1,
wherein the compensation region is spaced apart from the first electrode in a vertical direction of the drift region, and
wherein the Schottky diode further comprises a contact region of the second doping type connecting the compensation region to the first electrode.

14. The Schottky diode of claim 1, further comprising:
an insulating layer formed on top of the Schottky electrode.

15. The Schottky diode of claim 14, further comprising:
an anode electrode;
at least one electrically conducting via extending in the insulating layer between the anode electrode and the Schottky electrode.

16. The Schottky diode of claim 14, further comprising:
a cathode electrode;
at least one electrically conducting via extending in the insulating layer between the cathode electrode and the Schottky electrode.

17. A semiconductor arrangement, comprising:
the Schottky diode of claim 1; and
a lateral transistor device,
wherein the Schottky diode and the lateral transistor device are implemented in a same semiconductor body.

18. The semiconductor arrangement of claim 17,
wherein the lateral transistor device includes:
a drift region of the first doping type;
a body region of the second doping type; and
a drain region of the first doping type,
wherein the body region of the lateral transistor device and the shielding region of the Schottky diode at least approximately have a same doping concentration.

19. The semiconductor arrangement of claim 18,
wherein the drift region of the lateral transistor device and the drift region of the Schottky diode at least approximately have a same doping concentration.

20. The semiconductor arrangement of claim 18,
wherein the drain region of the lateral transistor device and the cathode region of the Schottky diode at least approximately have a same doping concentration.
